(19) United States
(12) Patent Application Publication
(10) Pub. No.: US 2009/0189653 A1
(43) Pub. Date: Jul. 30, 2009

(54) Phase Lock Loop Clock Distribution Method and System

(76) Inventors: David M. Friend, Rochester, MN (US); James D. Strom, Rochester, MN (US)

Correspondence Address: IBM-Rochester c/o Toler Law Group, 8500 Bluffstone Cove, Suite A201, Austin, TX, 78759, US

(21) Appl. No.: 12/020,794

(22) Filed: Jan. 28, 2008

(51) Int. Cl. H03L 7/06

(52) U.S. Cl. 327/156

(57) ABSTRACT

A method and apparatus and program use the quiet, regulated power supply inherent to the PLL to drive a CMOS buffer. In this manner, the CMOS buffer may distribute the reference clock in a manner that minimizes the power and space consumption associated with clock distribution processes.

### STATEMENT OF GOVERNMENTAL INTEREST

This invention was made with United States Government support under Agreement No. HR0011-07-9-0002 awarded by DARPA. The Government has certain rights in the invention.

### FIELD OF THE INVENTION

The present invention relates generally to clock distribution circuitry, and more particularly, to reducing power and space requirements associated with phase lock loops of high speed serial links.

### BACKGROUND OF THE INVENTION

The ability to perform high speed digital data transmissions is expected in any computing environment. In most cases, the transmission of digital data over long distances is accomplished by sending the data in a high speed serial format (i.e., one single bit after another) over a communication link designed to handle computer communications. In this fashion, data is transferred from one computer system to another, even if the computer systems are geographically remote.

In order for high speed serial transmission to occur, the digital data signal from inside the computer must be transformed from the parallel format into a serial format prior to transmission of the data over the serial communication link. This transformation is generally accomplished by processing the computer's internal data signal through a piece of computer equipment known as a serial link transmitter, or serializer. The function of the serializer is to receive a parallel data stream as input. By manipulating the parallel data stream, the serializer outputs a serial form of the data capable of high-speed transmission over a suitable communication link. Once the serialized data arrives at the desired destination, a deserializer converts the incoming data from the serial format to a parallel format for use within the destination computer system.

For high speed serializer/deserializer (HSS) link pairs, a phase lock loop (PLL) is used to create a phase lock based on the incoming signal. In one sense, the PLL keeps time for the serializer/deserializer pair. The PLL is internal to each device and is required to lock to the input clock frequency, perform the correct multiplication factor and maintain its output with minimal jitter. Jitter is the deviation in, or displacement of, some aspect of the pulses in a high frequency digital signal. A PLL is used because of its inherent feedback path that allows constant correction if a minor change is seen in the input signal edge position or period.

As shown in FIG. 1, the PLL 12 includes a phase/frequency detector (PD) 14 coupled to a charge pump (CP) 16, which is coupled to a voltage controlled oscillator (VCO) 18. A regulator (REG) 26 is included for the PLL circuitry 12 to supply a filtered/regulated version of the supply voltage (Vcc) to the VCO 18. The PD 14 compares the phase (FREQout) of the VCO signal filtered through a frequency divider (DIV) with that of the incoming signal (FREQin) and adjusts the control voltage to keep the VCO 18 in phase with the incoming signal. The PLL clock circuit 10 also includes CML buffers 28 that receive the reference clock signal and pass it on to another PLL (not shown.)

The analog circuitry 22 shown in FIG. 1 is particularly susceptible to jitter and noise. Consequently, band gap circuit 24 and regulator circuit 26 are typically used to regulate voltage and/or amperage. The band gap circuit 24 may generate a stable reference voltage, e.g., one volt. The regulator circuit 26 may isolate and filter the noise from the band gap circuit 24.

CML buffers 28 are used to process the clock signal because they are relatively insusceptible to noise. However, CML buffers 28 require a large amount of space on the microchip. That is, the CML buffers 28 are relatively large. A CML buffer 28 generally includes, for example, a differential transistor pair, a biasing transistor and a pair of load transistors. Each CML buffer 28 may occupy 2500 square microns of scarce space on a microchip. Component layout and space requirement considerations are especially critical in HSS design layouts.

Relatedly, the HSS reference clock distribution must be placed and routed amongst the regular chip logic, resulting in additional strains on the physical design for the microchip. Size limitations require that CML buffers 28 be positioned separate from and adjacent to the PLL 12.

CML buffers 28 additionally require relatively large amounts of power. For instance, each CML buffer 28 may consume around 11 mW of power. A typical distribution may contain at least 15 CML buffers, compounding the above space and power requirements.

For the above reasons, what is needed is a clock distribution circuit with decreased space and power requirements.

### SUMMARY OF THE INVENTION

The present invention provides an improved clock distribution circuit comprising a power source configured to generate a power signal, a phase lock loop circuit including regulating circuitry configured to regulate the power signal, a clock circuit configured to generate a clock signal, and a buffer circuit powered by the regulated power signal and configured to buffer and output the clock signal. In one embodiment, the buffer circuit comprises a CMOS (complementary metal oxide semiconductor) buffer.

According to an aspect of the invention, the buffer circuit is located within the phase lock loop circuit. In another or the same embodiment, another buffer circuit may be located within the phase lock loop circuit.

Embodiments may include another phase lock loop circuit configured to receive the buffered clock signal from the buffer circuit. Where desired, another phase lock loop circuit may be connected in series to the phase lock loop circuit and configured to receive the buffered clock signal from the buffer circuit. Alternatively, another phase lock loop circuit may be connected in a tree configuration to the phase lock loop circuit and may be configured to receive the buffered clock signal from the buffer circuit.

Aspects of the invention may include another phase lock loop configured to receive the buffered clock signal from the buffer circuit and may have substantially the same circuitry as the phase lock loop circuit. Another phase lock loop circuit may be configured to buffer and output another clock signal, and the clock signals may be either synchronous or asynchronous.

Another aspect of the invention includes an improved method of buffering a clock signal. The method comprises generating the clock signal, regulating a power signal within a phase lock loop circuit, powering a buffer circuit using the regulated power signal and buffering the clock signal using the buffer circuit. Where desired, the buffer circuit may comprise a CMOS buffer powered by the regulated power signal.

Embodiments may position the buffer circuit within the phase lock loop circuit. Where so configured, another buffer circuit may be positioned within the phase lock loop circuit. The buffered clock signal may be received at another phase lock loop. In one specific instance, the buffered clock signal may be received at another phase lock loop connected in series to the phase lock loop. Aspects of the invention may include receiving the buffered clock signal at another phase lock loop circuit connected in a tree configuration to the phase lock loop circuit. Other aspects may include configuring another phase lock loop circuit having substantially the same circuitry as the phase lock loop circuit, wherein the second phase lock loop circuit receives the buffered clock signal. Embodiments may further include buffering another clock signal using another phase lock loop circuit, wherein the clock signals are asynchronous. Alternatively, aspects may buffer another clock signal using another phase lock loop, wherein the clock signals are synchronous.

These and other advantages and features that characterize the invention are set forth in the claims annexed hereto and forming a further part hereof. However, for a better understanding of the invention, and of the advantages and objectives attained through its use, reference should be made to the Drawings and to the accompanying descriptive matter in which there are described exemplary embodiments of the invention.

### BRIEF DESCRIPTION OF THE DRAWINGS

FIG. 1 shows a microchip design plan having a PLL clock circuit according to the prior art.

FIG. 2 shows an HSS microchip design plan having a PLL clock circuit that is consistent with the underlying principles of the present invention.

FIG. 3 shows a PLL clock circuit in accordance with the principles of the present invention, and as may be employed within one of the PHY's of FIG. 2.

FIG. 4 shows a number of PHY's having serially connected PLL clock circuits in accordance with the underlying principles of the present invention.

FIG. 5 shows a plurality of PLL clock circuits configured in a tree structure in accordance with the underlying principles of the present invention.

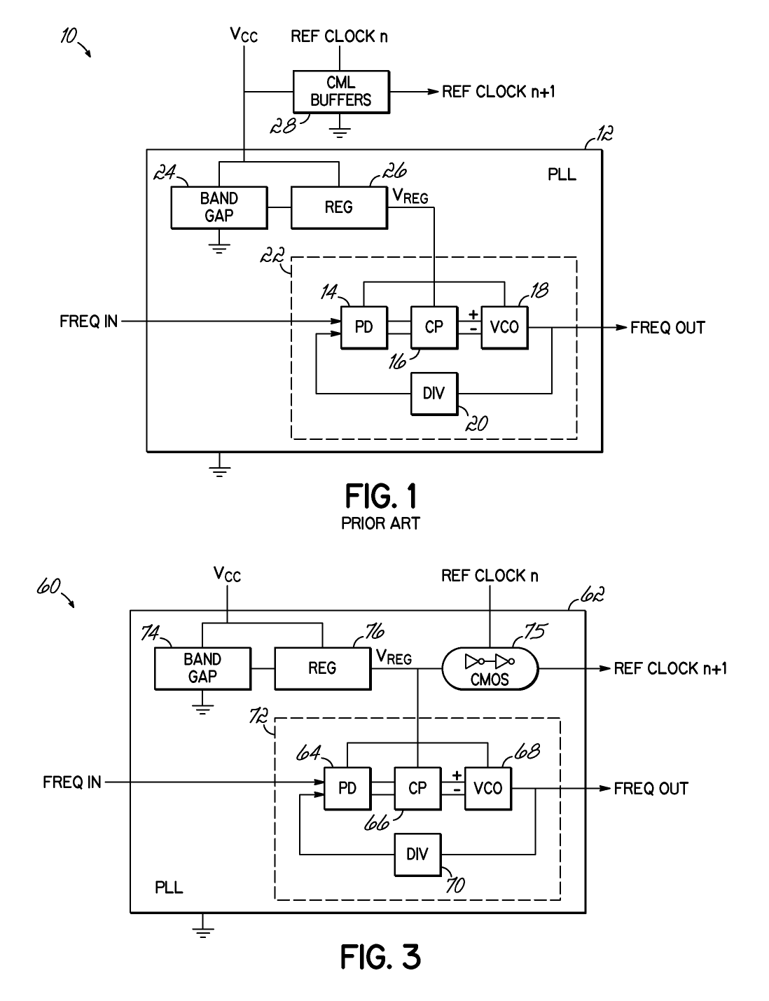

### DETAILED DESCRIPTION

In one respect, embodiments consistent with the invention may capitalize on the quiet, regulated power supply inherent to the PLL to drive a CMOS buffer. In this manner, the CMOS buffer may distribute the reference clock in a manner that minimizes the power and space consumption plaguing conventional clock distribution processes.

In many high HSS I\O intensive microchip designs, the HSS, or PHY macros, will be brick-walled in the microchip floor plan. The PLL's that exist in the PHY may each have a low noise, internally regulated power supply. Simple CMOS buffers that receive their power from the PLL regulated supply may be used to buffer the reference clock from PLL to PLL. The CMOS distribution performance may surpass that of conventional CML clock distribution schemes. The power supply noise reduction from the PLL regulator provides the CMOS clock buffer with superior deterministic and random jitter characteristics relative to CML buffer versions of clock distribution for HSS/PHY/PLL reference clocks.

In one configuration, a clock signal enters a microchip and is distributed among a number of PLL's. Each PLL typically drives a PHY. The PHY may perform the actual HSS logic. In this manner, the PLL provides a clock to the PHY. The PHY may drive data in the clocks over to the other PHY's on other chips. The reference clock signal needs to be free of noise. For this reason, the CMOS buffers typically receive power from built-in voltage and/or amperage regulators configured to isolate, filter and otherwise minimize noise and jitter.

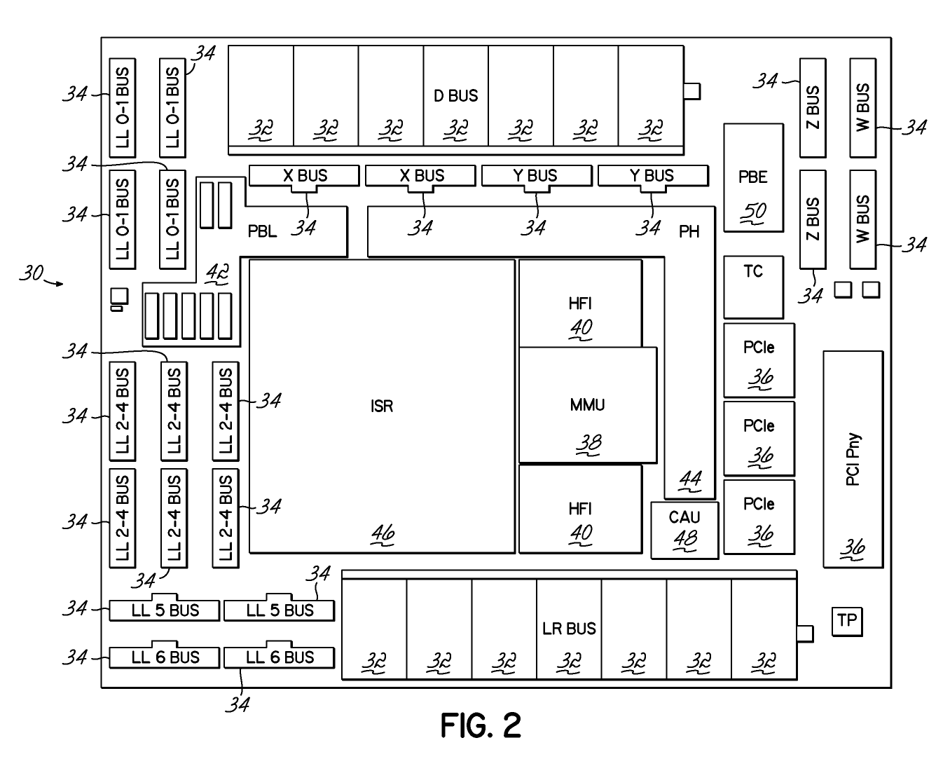

FIG. 2 shows a HSS microchip design plan having a PLL clock circuit 30 that is consistent with the underlying principles of the present invention. An HSS, or Serializer/Deserializer (SerDes), is a pair of functional blocks commonly used in high speed communications. These blocks convert data between serial data and parallel interfaces in each direction. More particularly, the design plan for the PLL clock circuit 30 includes a number of interconnected PHY circuits 32. A PHY may include a physical layer of the Open Systems Interconnection Basic Reference Model (OSI Model) that refers to a circuit that takes care of encoding and decoding between a pure digital domain (on-off) and a modulation in the analog domain. Such circuits are often used to interface a field-programmable gate array (FPGA), Complex Programmable Logic Device (CPLD), or a microcontroller to a specific type of bus or communications interface.

In the embodiment of FIG. 2, the PHY's 32 are connected to each other and the rest of the circuitry of the microchip design plan for the PLL clock circuit 30 via a series of busses 34. As shown in FIG. 2, the design plan for the PLL clock circuit 30 also includes Peripheral Component Interconnections (PCI) 36, as well as a memory management unit circuit 38 and high frequency injection circuits 40. Still other components include PBL 42, PH 44, ISR 46, CAU 48 and PBE circuitry 50.

FIG. 3 shows a PLL clock circuit 60 in accordance with the principles of the present invention, and as may be employed within one of the PHY's 32 of FIG. 2. More particularly, the PLL clock circuit 60 includes a CMOS buffer 75 used to distribute the reference clock in a manner that consumes less space and power than prior art CML buffer configurations. The PLL clock circuit 60 may use a regulated power supply that is in the PLL 62. Of note, if the CMOS buffer 75 was powered by a conventional microchip power supply and used to distribute the clock, the reference clock would have too much jitter.

The CMOS buffer 75 may include a CMOS circuit. The CMOS buffer 75 typically comprises a cascade of two CMOS inverters, each of which may include a NMOS transistor and a PMOS transistor.

As shown in FIG. 3, the PLL clock circuit 60 includes a PLL 62 having a phase/frequency detector (PD) 64 coupled to a charge pump (CP) 66. The charge pump (CP) 66 may couple to a voltage controlled oscillator (VCO) 68. To protect the analog circuitry 72 from undue noise, the PLL clock circuit 60 includes a band gap circuit 74 and regulator circuit 76. The band gap 74 and regulator circuit 76 may filter and regulate the supply of voltage (Vcc) to the voltage controlled oscillator (VCO) 68. The regulator circuit 76 may more particularly filter out noise and supply a smaller amount of current. The phase/frequency detector (PD) 64 may compare the phase (FREQout) of the voltage controlled oscillator (VCO) 68 signal filtered through a frequency divider (DIV) 70 with that of the incoming signal (FREQin) and adjust the control voltage to keep the voltage controlled oscillator (VCO) 68 in phase with the incoming signal.

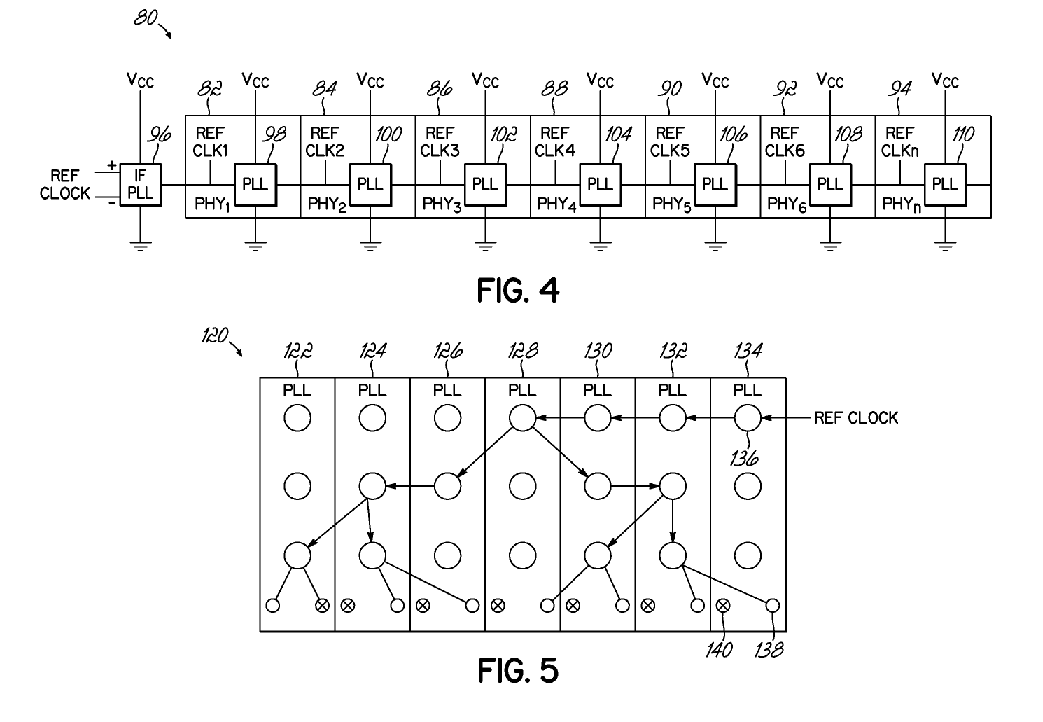

FIG. 4 shows a plurality of serially connected CMOS buffers. More particularly, FIG. 4 shows a number of PHY's 82, 84, 86, 88, 90, 92, 94 having serially connected PLL circuits 98, 100, 102, 104, 106, 108, 110, respectively, in accordance with the underlying principles of the present invention.

As shown in FIG. 4, the circuit 80 includes a series of HSS macros, or PHY's 82, 84, 86, 88, 90, 92, 94. Each PHY 82, 84, 86, 88, 90, 92, 94 includes a PLL 98, 100, 102, 104, 106, 108, 110, respectively. Each PLL 98, 100, 102, 104, 106, 108, 110, in turn, may include a CMOS buffer 75, such as that shown in FIG. 3. The configuration of the PLL's 98, 100, 102, 104, 106, 108, 110 of FIG. 4 may have particular application where the reference clock signals may be asynchronous as between the respective PHY's 82, 84, 86, 88, 90, 92, 94. The relative arrangement of the respective PLL's 98, 100, 102, 104, 106, 108, 110 thus supports processes that do not depend on the occurrence of common timing signals. As such, embodiments consistent with the invention may accommodate different application requirements that are particular to relative clock arrival time.

The circuit 80 is configured to receive and distribute a reference clock signal from the intermediate frequency (IF) PLL 96. The reference clock signal may then be passed on, e.g., in daisy-chained fashion, between the serially connected PLL buffers 98, 100, 102, 104, 106, 108, 110 for the PLL's. That is, reference clock signal 1 may be processed by the PLL 98 to generate reference clock signal 2, which may then be supplied as an input to PLL 100, and so on, until reference clock signal “n” is provided to the last PLL 110 in the circuit 80. As shown, the circuit 80 of PHY's 82, 84, 86, 88, 90, 92, 94 may be suited for inclusion within the design plan for the PLL clock circuit 30 of FIG. 2.

FIG. 5 shows a plurality of PLL's 122, 124, 126, 128, 130, 132, 134 configured in a tree structure. The PLL's 122, 124, 126, 128, 130, 132, 134 may each include a repeatable, or standard, number of CMOS buffers 136. The interchangeability provided by this feature may enable greater design flexibility and economy.

In one sense, the clock referenced signal may be distributed throughout the PLL's 122, 124, 126, 128, 130, 132, and 134 and the associated CMOS buffers 136 in an h-tree distribution pattern. This configuration may have particular application where the clock signal must be synchronized as between the respective PLL's 122, 124, 126, 128, 130, 132, 134. That is, the embodiment shown in FIG. 5 may be suited for applications where communication without time delay is preferred, and/or where the reference clock signals arrive concurrently.

Because some of the CMOS buffers 136 connect to two CMOS buffers 136, while others connect to only one, dummy receiver loads 140 may be used in addition to reference clock receivers 138 to help balance the distribution process. In this manner, embodiments consistent with the invention may balance the loads to each of the PLL's 122, 124, 126, 128, 130, 132, 134.

In FIG. 5, to achieve greater balance, the reference clock signal may be delivered to a centrally positioned CMOS buffer 136, such as one positioned in PLL 128. In this manner, the h-tree distribution function may be achieved.

While the present invention has been illustrated by a description of various embodiments and while these embodiments have been described in considerable detail, it is not the intention of the Applicants to restrict, or in any way limit the scope of the appended claims to such detail. For instance, because HSS applications are well understood and documented, many aspects of the invention have been described in terms of HSS based concepts. However, the HSS based concepts are used principally for ease of explanation. The invention is not limited to interactions with a HSS environment. Moreover, while CMOS buffers are advantageous in many embodiments, one skilled in the art will recognize that other buffers may be connected to the internal power supply of the PLL to achieve other desirable results. The invention in its broader aspects is therefore not limited to the specific details, representative apparatus and method, and illustrative example shown and described. Accordingly, departures may be made from such details without departing from the spirit or scope of Applicants' general inventive concept.

What is claimed is:

1. A circuit, comprising:
a power source configured to generate a power signal;
a phase lock loop circuit including regulating circuitry configured to regulate the power signal;
a clock circuit configured to generate a clock signal; and
a buffer circuit powered by the regulated power signal and configured to buffer and output the clock signal.

2. The circuit of claim 1, wherein the buffer circuit includes a CMOS buffer.

3. The circuit of claim 1, wherein the buffer circuit is located within the phase lock loop circuit.

4. The circuit of claim 1, further comprising another buffer circuit located within the phase lock loop circuit.

5. The circuit of claim 1, further comprising another phase lock loop circuit configured to receive the buffered clock signal from the buffer circuit.

6. The circuit of claim 1, further comprising another phase lock loop circuit connected in series to the phase lock loop circuit and configured to receive the buffered clock signal from the buffer circuit.

7. The circuit of claim 1, further comprising another phase lock loop circuit connected in a tree configuration to the phase lock loop circuit and configured to receive the buffered clock signal from the buffer circuit.

8. The circuit of claim 1, further comprising another phase lock loop circuit configured to receive the buffered clock signal from the buffer circuit and having substantially the same circuitry as the phase lock loop circuit.

9. The circuit of claim 1, further comprising another phase lock loop circuit configured to buffer and output another clock signal, wherein the clock signals are asynchronous.

10. The circuit of claim 1, further comprising another phase lock loop circuit configured to buffer and output another clock signal, wherein the clock signals are synchronous.

11. A method of buffering a clock signal, the method comprising:
generating the clock signal;
regulating a power signal within a phase lock loop circuit;
powering a buffer circuit using the regulated power signal; and
buffering the clock signal using the buffer circuit.

12. The method of claim 11, wherein powering the buffer circuit using the regulated power signal further include powering a CMOS buffer using the regulated power signal.

13. The method of claim 11, further comprising positioning the buffer circuit within the phase lock loop circuit.

14. The method of claim 11, further comprising positioning another buffer circuit within the phase lock loop circuit.

15. The method of claim 11, further comprising receiving the buffered clock signal at another phase lock loop circuit.

16. The method of claim 11, further comprising receiving the buffered clock signal at another phase lock loop circuit connected in series to the phase lock loop circuit.

17. The method of claim 11, further comprising receiving the buffered clock signal at another phase lock loop circuit connected in a tree configuration to the phase lock loop circuit.

18. The method of claim 11, further comprising configuring another phase lock loop circuit having substantially the same circuitry as the phase lock loop circuit, wherein the second phase lock loop circuit receives the buffered clock signal.

19. The method of claim 11, further buffering another clock signal using another phase lock loop circuit, wherein the clock signals are asynchronous.

20. The method of claim 11, further buffering another clock signal using another phase lock loop circuit, wherein the clock signals are synchronous.
